(19) United States
(12) Patent Application Publication
(10) Pub. No.: US 2008/0237683 A1
(43) Pub. Date: Oct. 2, 2008

(54) HIGH-K TRILAYER DIELECTRIC DEVICE AND METHODS

(76) Inventors: Kyu S. Min, San Jose, CA (US); Thomas M. Graettinger, Boise, ID (US)

Correspondence Address: SCHWEGMAN, LUNDBERG & WOESSNER, P.A., P.O. BOX 2938, MINNEAPOLIS, MN, 55402, US

(21) Appl. No.: 11/694,059

(22) Filed: Mar. 30, 2007

(51) Int. Cl. H01L 29/788; H01L 21/336

(52) U.S. Cl. 257/316; 438/264; 257/E21.409; 257/E29.3

(57) ABSTRACT

Methods and structures are described for reducing a gate leakage current and increasing gate coupling ratio in a semiconductor device. In some embodiments, nitride layers are used to limit the oxidation of adjacent silicon gate regions due to oxygen in an intermediate insulator. In various embodiments, the intermediate insulator includes a high-κ dielectric material. Apparatus according to embodiments of the invention are also disclosed.

### TECHNICAL FIELD

The information disclosed herein relates generally to semiconductors, including semiconductor memory.

### BACKGROUND

The semiconductor device industry has a market driven need to reduce the size of devices used in products such as processor chips, mobile telephones and memory, such as flash memory. Currently, the semiconductor industry relies on the ability to reduce or scale the dimensions of its basic devices. This can include scaling dielectric regions, which are often formed of silicon dioxide (SiO₂). However, increased scaling and other requirements in microelectronic devices have made SiO₂ less useful because of its band gap and dielectric properties. Thus, there is a general need for new dielectric structures as device dimensions shrink.

### BRIEF DESCRIPTION OF THE DRAWINGS

FIG. 1 illustrates a floating gate device according to various embodiments of the invention.

FIG. 2 is a flow chart illustrating a method according to various embodiments of the invention.

FIG. 3 illustrates capacitive coupling according to various embodiments of the invention.

FIG. 4 illustrates gate leakage current according to various embodiments of the invention.

FIG. 5 illustrates gate leakage current according to various embodiments of the invention

FIG. 6 illustrates a circuit module according to various embodiment of the invention.

FIG. 7 illustrates a circuit module as a memory module according to various embodiment of the invention.

FIG. 8 is a block diagram illustrating an electronic system according to various embodiment of the invention.

### DETAILED DESCRIPTION

The following description and the drawings sufficiently illustrate specific embodiments of the invention to enable those skilled in the art to practice them. Other embodiments may incorporate structural, logical, electrical, process, and other changes. Examples merely typify possible variations. Portions and features of some embodiments may be included in, or substituted for, those of other embodiments. Embodiments of the invention set forth in the claims encompass all available equivalents of those claims. Embodiments of the invention may be referred to herein, individually or collectively, by the term “invention” merely for convenience and without intending to limit the scope of this application to any single invention or inventive concept if more than one is in fact disclosed.

In the following description, the “substrate” refers generally to any structure on which integrated circuits are formed and also to such structures during various stages of integrated circuit fabrication. The term substrate is understood to include a semiconductor wafer and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to generally include n-type and p-type semiconductors and the term insulator or dielectric is defined to include any material that is less electrically conductive than the materials referred to as conductors. The term “high-κ” refers, generally, to a dielectric constant that is substantially greater than 3.9.

Reducing the device dimensions, including its dielectric portions, is desirable for achieving a high density of electronic devices on a wafer. However, reducing dimensions can produce higher device leakage currents and lower device breakdown voltages. A dielectric's dimensions can become increasingly relevant less than 50 nm, particularly for a floating-gate based flash memory device. A way to reduce the thickness of a dielectric region without a proportionate increase in the leakage current or reduction in dielectric breakdown voltage is to use an material with a high dielectric constant.

A useful metric for characterizing a dielectric using its actual physical thickness (tₐ) is equivalent oxide thickness (t_{eq}). t_{eq} can be considered the thickness of a theoretical SiO₂ layer that achieves the same capacitance density of a specified dielectric. For a specified capacitance, tₐ of a dielectric material can be related to its t_{eq} by

t_{eq}=(κₒₓ/κ)tₐ=(3.9/κ)tₐ,

where κ is the dielectric constant of the specified dielectric and κₒₓ=3.9 is the dielectric constant for SiO₂. Thus, materials with a dielectric constant greater than SiO₂ can provide a t_{eq} that is smaller than tₐ. For example, Si₃N₄ with a dielectric constant of about 7.5 and a thickness of about 20 nm can be used in place of SiO₂. The resulting t_{eq} is about 10.4 nm, excluding depletion/inversion layer effects. Typical values for t_{eq} range from about 5 nm to about 13 nm, but can be more or less, depending on the dielectric constant. Therefore, materials with a dielectric constant larger than SiO₂ allow the dielectric to be thinner without a commensurate loss in capacitance, which in turn assists in the scaling of semiconductor devices.

Another useful metric for characterizing a dielectric is degree of capacitive voltage coupling between conductive gates expressed as the gate coupling ratio (GCR). The GCR can be represented as,

GCR=C_{ig}/C_{T},

where C_{ig} is the capacitance of the dielectric material between the conductive gates and C_{T} is the total capacitance of the structure. Since C_{ig} is proportional to the dielectric constant of a material (κ_{ig}), a dielectric constant that is greater than SiO₂ can increase the GCR beyond that of SiO₂. Thus, use of materials with ever larger dielectric constants can enable a reduction in gate leakage current without a corresponding reduction in gate voltage in a device, such as a flash memory device. Materials with a dielectric constant larger than that of SiO₂ are called as high-κ dielectrics materials. Examples of high-κ dielectrics include, but are not limited to, the oxides of aluminum (Al), hafnium (Hf), zirconium (Zr), lanthanum (La), tantalum (Ta), tungsten (W), titanium (Ti), dysprosium (Dy), yttrium (Y) and scandium (Sc), the nitrides of Al, Si and boron (B), the oxynitrides SiOₓN_{y} and HfOₓN_{y}, the mixed oxides HfAlOₓ, TiAlOₓ and ZrAlOₓ, the silicates HfSiOₓ, ZrSiOₓ and TaSiOₓ, and the perovskites SrTiOₓ and LaTiOₓ. Dielectric constant values for high-κ dielectrics materials range from about 7 to about 100, depending on the dielectric.

Despite the possible enhancement in voltage coupling between gates, process integration issues may limit use of many high-κ dielectric materials with silicon, particularly with the high-κ dielectrics that contain oxygen or are oxide-based. During formation of an oxide-based high-κ dielectric on polysilicon, some SiO₂ may form due to a reaction between oxygen and silicon. The resulting structure is a parasitic layer of SiO₂ separating the polysilicon gate from the high-K dielectric layer. A composite dielectric may also form that includes oxygen that is reactive with silicon. This can happen, for example, during the deposition and processing of a nitride such as silicon nitride, where the unintentional incorporation of oxygen can produce a silicon oxynitride mixture having a ratio of Si/N that is other than 3/4. If, as with the case of a floating gate structure, such as a nonvolatile memory device, a second polysilicon gate is formed on the oxide-based high-κ dielectric layer, then a second parasitic layer of SiO₂ separating the second polysilicon gate from the high-κ dielectric layer may form. The resulting dielectric composite consists of stacked parasitic SiO₂ and high-κ dielectric layers that can have a lower dielectric strength and lower effective dielectric constant than that of the high-κ dielectric alone. In such a case, the capacitance can be modeled as three dielectrics in series, where the t_{eq} of the dielectric stack is the sum of the thicknesses of the two parasitic SiO₂ layers and a multiplicative factor of the tₐ of the high-κ inter-gate dielectric being formed. Considering only SiO₂ (i.e., no mixtures with SiO₂) then,

t_{eq}=t_{acSiO2}+t_{afSiO2}+(3.9/κ)tₐ,

where t_{acSiO2} and t_{afSiO2} are the actual thicknesses of the SiO₂ layers formed, for example, at the control and floating gate, respectively. A high-κ dielectric material with a dielectric constant of 10 and a thickness of about 20 nm, in series with 2 nm parasitic SiO₂ formed at each gate results in a t_{eq} of about 11.8 nm, excluding any depletion/inversion layer effects. Thus, if SiO₂ is formed in the process, the t_{eq} will be increasingly limited by the thicknesses of the SiO₂ layers.

To prevent the formation of SiO₂, a suitable barrier layer can be interposed between the polysilicon and the desired high-κ dielectric. Such a barrier layer can be formed of one or more materials that bind oxygen in such a way as to render oxygen in the barrier layer substantially non-reactive with silicon. Oxygen so bound in the barrier layer is unable to cause a sufficient reduction in the dielectric constant of the barrier layer to approach that of SiO₂.

Embodiments of the invention address formation of SiO₂ between a high-κ dielectric containing oxygen and a layer of polysilicon. One or more nitride barrier layers can be inserted as an oxygen diffusion barrier between polysilicon and high-κ dielectric. In some embodiments, one or more layers can be configured to reduce the oxidation of polysilicon due to an oxide-containing high-κ dielectric. In some embodiments, one or more nitride barrier layers are formed of a silicon nitride. In various embodiments, one or more nitride barrier layers are formed of a AlN, a BN, or an oxynitride such as SiOₓN_{y} and HfOₓN_{y}. In some embodiments, the one more nitride barrier layers are a composite including two or more of a silicon nitride and a nitride such as AlN and BN. In some embodiments, at least one layer is inserted between a polysilicon gate and a high-κ dielectric that includes oxygen in a form that is non-reactive with silicon.

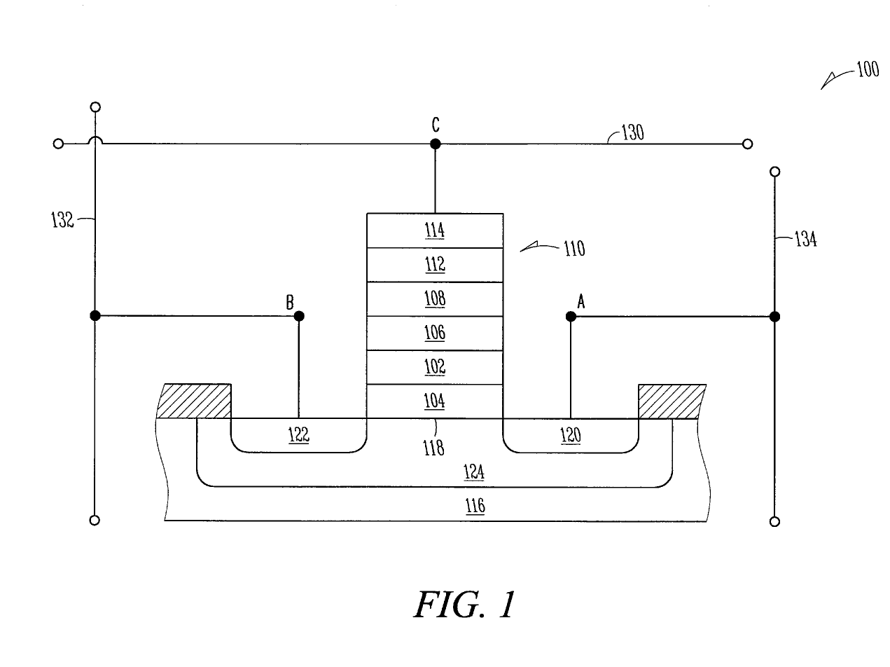

FIG. 1 is a schematic illustrating a floating gate device 100 according to various embodiments of the invention. In this example, the floating gate device 100 includes a stacked gate region 110 on the substrate 116. The stacked gate region 110 includes a floating gate region 102 on a gate insulator 104 adjacent to a channel region 118. In some embodiments, the gate insulator 104 is a tunnel oxide. A first dielectric layer 106 is in contact with floating gate region 102 and a second dielectric layer 108. A third dielectric layer 112 is in contact with the second dielectric layer 108 and a control gate region 114. The floating gate region 102 and the control gate region 114 can be formed of silicon, such as an n-doped polysilicon. In some embodiments, the floating gate region 102 and/or the control gate region 114 are formed of n-doped amorphous silicon. In some embodiments, the dielectric constant of the second dielectric layer 108 is greater than the dielectric constant of the first dielectric layer 106 and/or the third dielectric layer 112. In some embodiments, the dielectric constant of the second dielectric layer 108 is greater than about 7. In some embodiments, the dielectric constant of the second dielectric layer 108 includes a range from about 7 to about 50. In various embodiments, the dielectric constant of the first dielectric layer 106 and/or the third dielectric layer 112 is greater than about 4. In some embodiments, the dielectric constant of the first dielectric layer 106 and/or the third dielectric layer 112 includes a range from about 4 to about 50. In some embodiments, the first dielectric layer 106, the second dielectric layer 108, and the third dielectric layer 112 have a combined thickness that is less than or equal to 50 nm.

The first dielectric layer 106, the second dielectric layer 108, and the third dielectric layer 112 form a composite dielectric stack. Layer 106 and layer 112 can be formed of the same material or of a different material, depending on the effective dielectric constant desired between gate regions 102, 114. In some embodiments, the first dielectric layer 106 and the third dielectric layer 112 are barrier layers that prevent the diffusion of oxygen between the second dielectric layer 108 and the floating gate region 102 and the control gate region 114, respectively. In some embodiments, layer 106 and layer 112 are formed to prevent oxygen contained in the second dielectric layer 108 from reacting with the floating gate region 102 and/or with the control gate region 114, respectively. In such an embodiments, the oxygen entering layer 106 and/or 112 become sufficiently bound to the constituents in layers 106, 112 to render the oxygen substantially non-reactive with the material used for the floating gate region 102 and the control gate region 114. In some embodiments, at least one of the first dielectric layer 106 and the third dielectric layer 112 include a nitride such as a silicon nitride, an aluminum nitride and a boron nitride. In some embodiments, at least one of the first dielectric layer 106 and the third dielectric layer 112 include an oxynitride such as a SiOₓN_{y} and HfOₓN_{y}.

In some embodiments the second dielectric layer 108 includes at least one oxide of Al, Dy, Hf, Zr, Sc, La, Ta, Y, W, and Ti. In some embodiments, the second dielectric layer 108 is formed as a composite of two or more oxides of Al, Dy, Hf, Zr, Sc, La, Ta, Y, W, and Ti. In some embodiments, the layer 108 includes a nitride, such as a silicon nitride, AlN, and BN. In some embodiments, the layer 108 is formed as a composite of two or more nitrides including Si, Al, and B. In some embodiments, the layer 108 includes at least one nitride containing at least one of Si, Al, and B, and at least one oxide containing one or more of Al, Dy, Hf, Zr, Sc, La, Ta, Y, W, and Ti. In various embodiments, the layer 108 includes one or more of an oxynitride such as SiOₓN_{y} and HfOₓN_{y}, a binary nitride such as SiₓN_{y}, AlN, BN, a mixed oxide such as HfAlOₓ, TiAlOₓ and ZrAlOₓ, a silicate such as HfSiOₓ, ZrSiOₓ, and TaSiOₓ, and a perovskite such as SrTiOₓ and LaTiOₓ.

The floating gate device 100 can include a well region 124, such as a p-doped well or an n-doped well, to isolate device 100 from other devices further formed in the substrate 116. Drain region 122 can be connected at terminal B to the bit line 132. The control gate 114 can be connected at terminal C to the word line 130. The source region 120 can be connected at terminal A to the source line 134 to remove charge trapped in the channel region 118 due to a voltage on the floating gate region 102. The drain region 122 and the source region 120 are n-doped regions, but may be formed as p-doped regions, depending on the device characteristics desired. Although not shown in FIG. 1, one of ordinary skill in the art will recognize that the bit line 132, the word line 130 and the source line 134 can be further coupled to other floating gate devices, other non-floating gate devices and/or conductors that can be used for transmitting and receiving voltage signals.

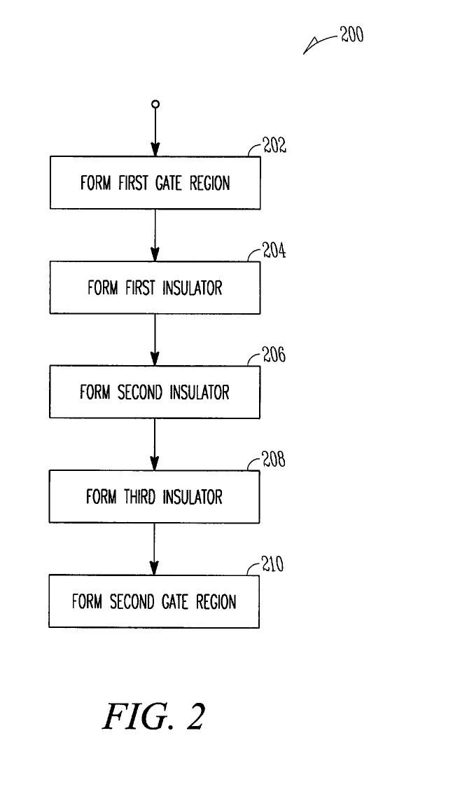

FIG. 2 is a flow chart 200 illustrating a method according to various embodiments of the invention. In this example, the method begins at block 202 by forming a conductive floating gate on a gate dielectric located between two or more doped semiconductor regions. The conductive floating gate is n-type, but may be p-type, depending on the desired performance characteristics. The doped semiconductor regions can be n-type or p-type, depending on the desired device characteristics. The gate dielectric can be a tunnel oxide layer or an oxide of a suitable thickness to perform an intended charge gating function or achieve a desired current-voltage characteristic. The doped semiconductor regions can be formed in a substrate, an epitaxial layer formed on a substrate, or a well region such as a p-well or n-well formed in the substrate. The substrate can be any suitable material such as Si, SiGe, SiGeC, silicon-on-sapphire, silicon-on insulator, and the like. The conductive floating gate region and the gate dielectric can be used in combination to form a conductive channel operatively coupling the two or more doped semiconductor regions. The conductive floating gate can be formed of polysilicon or single crystal silicon. In an embodiment, the conductive floating gate is formed of amorphous silicon.

At block 204, a first insulator can be formed over and in substantial contact with the conductive floating gate. The first insulator can also be formed over and in substantial contact with the sidewalls of the conductive floating gate. The first insulator includes a material that is substantially oxygen free, such as a silicon nitride. The first insulator can also be a material in which any oxygen contained therein is rendered substantially non-reactive with silicon. In some embodiments, the first insulator is a diffusion barrier formed to prevent oxygen diffusion between the conductive floating gate and one or more other dielectric layers. In some embodiments, the first insulator is formed to prevent an oxidation reaction involving the conductive floating gate. The first dielectric can be formed of nitride including at least one of Si, Al, and B. In some embodiments, forming the first insulator includes forming a layer containing one or more oxynitrides of Si, Al, B, Hf, Zr, La, Ta, W, and Ti.

At block 206, a second insulator is formed over and in substantial contact with the first dielectric layer. The second insulator layer can include an oxide, a nitride or a mixture one or more oxides and one or more nitrides. The second insulator is formed with a dielectric constant that is greater than or equal to the dielectric constant of the first insulator. In some embodiments, the second insulator includes one or more oxides of Al, Dy, Hf, Zr, Sc, La, Ta, Y, W, and Ti, or one or more nitrides of Si, Al, B, Hf, Zr, La, Ta, W, and Ti. In some embodiments, forming the second layer includes forming a composite insulator of at least one oxide of Al, Dy, Hf, Zr, Sc, La, Ta, Y, W, and Ti and at least and at least one nitride of Si, Al, B, Hf, Zr, La, Ta, W, and Ti.

At block 208, a third insulator is formed over and in substantial contact with the second insulator. The third insulator can include a material that is substantially oxygen free, such as a silicon nitride, or a material in which any oxygen contained therein is rendered substantially non-reactive with silicon. The third insulator can be formed as a nitride layer containing at least one of Si, Al, and B. In some embodiments, forming the third insulator includes forming a layer containing one or more oxynitrides of Si, Al, B, Hf, Zr, La, Ta, W, and Ti.

The third insulator can be formed with a dielectric constant that is less than or equal to the second dielectric constant associated with the second insulator. In some embodiments, the third insulator is barrier layer formed to prevent oxygen diffusing from the second dielectric to a region of silicon. In some embodiments, the third insulator is a barrier formed to prevent an oxidation reaction between the second insulator and a silicon-based gate region in contact with the third dielectric layer. In some embodiments, the third insulator is formed of substantially the same material as the first insulator such that the dielectric constants of the first and third insulators are substantially equal. In an embodiment, the first, second and third insulators are formed of substantially the same material.

At block 210, a conductive control gate region is formed over and in substantial contact with the third insulator. The conductive control gate region can be formed such that the sidewalls of the control gate region are enclosed by and in substantial contact with the third insulator. The conductive control gate region can be formed of silicon, such as n-doped polysilicon or an n-doped single crystal silicon. In some embodiments, the conductive control gate region is formed of n-doped amorphous silicon. In some embodiments, the conductive control gate region is formed of substantially the same material as the conductive floating gate region.

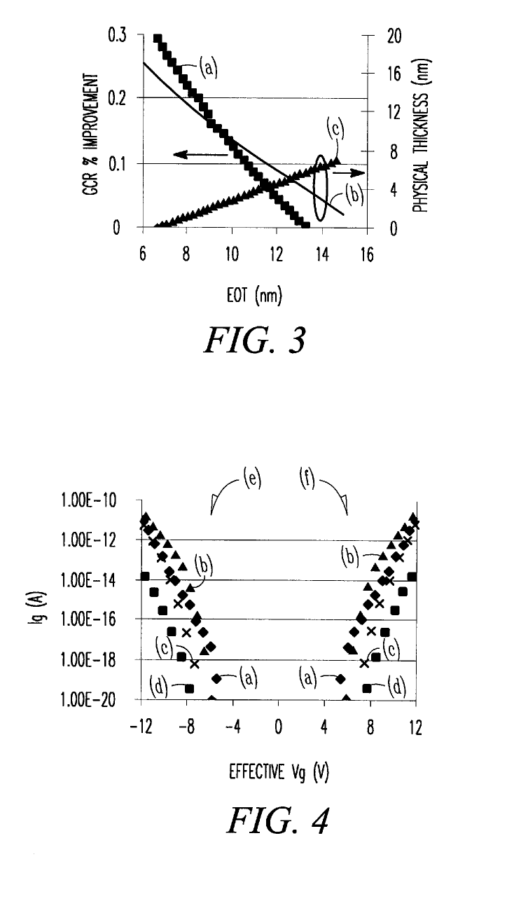

FIG. 3 is a graph 300 illustrating capacitive coupling ratio according to various embodiments of the invention. Here, an improvement in GCR is shown as curve (a) for the floating gate device 100 as a function of t_{eq}. In this simulation, a three layer dielectric stack formed of SiO₂— Al₂O₃—SiO₂ is located between conductive polysilicon control and floating gates. The total physical thickness for the three layers is essentially constant at 16 nm. Curve (b) represents the thickness of the Al₂O₃ and curve (c) represents the equal thicknesses of the two SiO₂ layers adjoining the polysilicon gates. As shown in curve (a), GCR increases about 30% as the physical thickness of the Al₂O₃ increases to about 16 nm and the physical thicknesses of the SiO₂ layers adjoining each polysilicon gates decrease to zero. The above illustrates formation of SiO₂ along the gate regions can increase t_{eq} and reduce the GCR of a floating gate device. A reduced GCR can decrease voltage coupling between the control and floating gates, which in a flash memory cell, can require higher voltages to transfer charge to the floating gate.

FIG. 4 is a graph 400 illustrates gate leakage current according to various embodiments of the invention. In this simulation, the floating gate leakage current is plotted for the floating gate device 100 as a function of the effective floating gate voltage (V_{g}) for erasure (e) and programming (f) modes for four different inter-poly dielectrics, each dielectric formed of three insulator layers. The floating and control gates are n-doped polysilicon. The thicknesses of the inter-poly dielectrics are 154 Å. Curve (a) represents a 50 Å Si₃N₄ layer located between two SiO₂ layers of equal 52 Å thicknesses. Curve (b) represents a 74 Å Al₂O₃ layer between two SiO₂ layers of equally 40 Å thicknesses. Curve (c) represents a 134 Å Al₂O₃ layer between two SiO₂ layers of equally 10 Å thicknesses. Curve (d) represents a 154 Å Al₂O₃ layer without the SiO₂ layers. The data demonstrate for both programming (f) and erasure (e) modes of operation, the floating gate leakage current decreases by about three orders of magnitude, from a maximum of about 10 pA to about 10 fA, as the SiO₂ layers are reduced to zero thicknesses. The above illustrates that formation of parasitic SiO₂ can increase the floating gate leakage current.

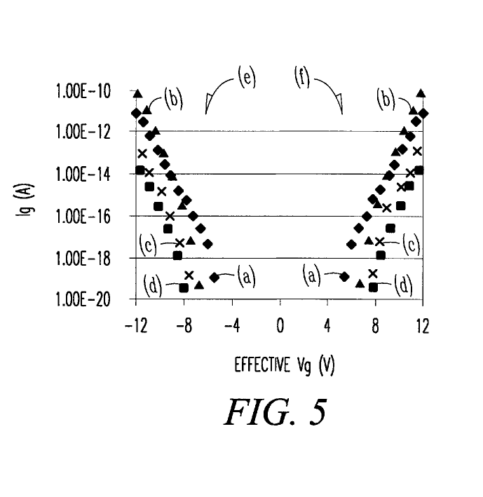

FIG. 5 is a graph 500 illustrating gate leakage current according to various embodiments of the invention. In this simulation, the floating gate leakage current is plotted for the floating gate device 100 as a function of the effective floating gate voltage (V_{g}) for erasure (e) and programming (f) modes for four different inter-poly dielectrics, each of the dielectrics is formed of three insulator layers. The floating and control gates are n-doped polysilicon. The thicknesses of the inter-poly dielectric stacks is 154 Å. Curve (a) represents a 50 Å Si₃N₄ layer located between two SiO₂ layers of equal 52 Å thicknesses. Curve (b) represents a 74 Å Al₂O₃ layer located between two Si₃N₄ layers of equally 40 Å thicknesses. Curve (c) represents a 134 Å Al₂O₃ layer located between two Si₃N₄ layers of equally 10 Å thicknesses. Curve (d) represents a 154 Å Al₂O₃ layer without Si₃N₄ layers. The data demonstrate for both programming (f) and erasure (e) modes of operation, the floating gate leakage current can be about two orders in magnitude lower, from a maximum of about 10 pA to about 100 fA, for the inter-poly dielectric with a 10 Å Si₃N₄ adjoining each of the polysilicon gates over that of an inter-poly dielectric with adjoining SiO₂ layers (curves (a),(b),(c) of FIG. 4). The above illustrates an inter-poly dielectric with Si₃N₄ separating an oxide-containing high-κ dielectric from the silicon-containing floating and control gates can reduce the floating gate leakage current of a floating gate-based flash memory device.

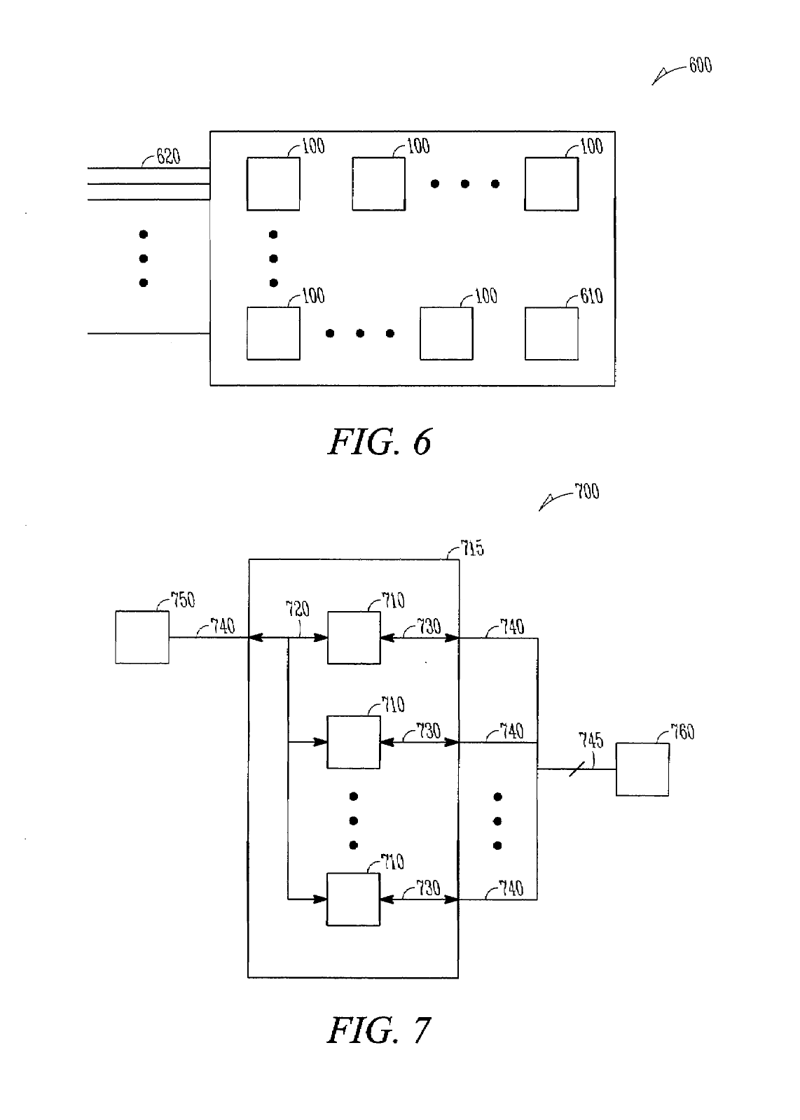

FIG. 6 illustrates a circuit module 600 according to various embodiment of the invention. As shown in FIG. 6, at least one floating gate device 100 can be combined into a circuit module 600 to enhance or extend functionality. The circuit module 600 can comprise a combination floating gate devices 100 representing a variety of functions. It should be understood that the floating gate devices 100 in the circuit module 600 can be formed as a single integrated circuit. Circuit module 600 can contain other devices 610 in accordance with embodiments of the invention, including one or more floating gate devices 100, as shown in FIG. 1.

Some examples of a circuit module include memory modules, device drivers, power modules, communication modems, processor modules and application-specific modules, and may include multilayer and multichip modules. The circuit module 600 may be a subcomponent of a variety of electronic systems, such as an imager, a digital camera, a television, game controller, a cell phone, a personal computer, a personal digital assistant, a network server such as a file server or an application server, an automobile, an industrial process control system, an aircraft and others. The circuit module 600 includes a variety of leads 620 that can be coupled to the floating gate devices 100, providing unilateral or bilateral communication and control.

FIG. 7 illustrates a circuit module as a memory module 700, according to various embodiment of the invention. A memory module 700 can include multiple memory devices 710 contained on a support 715 (the number generally depending upon the desired bus width and the desire for parity checking). In some embodiments, the memory module 700 accepts a command signal from an external processor 760 on a command link 720 and provide for data input and data output on data links 730. The command link 720 and data links 730 may be connected to leads 740 extending from the support 715. The leads 740 are shown for conceptual purposes and are not limited to the positions shown in FIG. 7. At least one of the memory devices 710 contain an integrated circuit structure or element in accordance with embodiments of the invention, including one or more floating gate devices 100, as shown in FIG. 1.

One or more of the memory devices 710 can be coupled a processor 760 by a bus 745 providing bidirectional communication for some form of observation, manipulation and control or direction of inputs from or outputs to a user interface 750. Some examples of a user interface 750 include a keyboard, a pointing device, a joystick, a display, a keypad, as well as other human-machine interfaces. Examples of a processor include a microprocessor, a digital signal processor and a controller, such as a microcontroller. It should be understood that the one or more memory devices 710 in the memory module 700 can be replaced by a single integrated circuit. Furthermore, the memory module 700 may be a subcomponent of a larger electronic system, including a processor. It should also be understood by those of ordinary skill in the art after reading this disclosure that at least one of the memory modules 700 may contain an integrated circuit structure or element in accordance with embodiments of the invention, including one or more floating gate devices 100, as shown in FIG. 1.

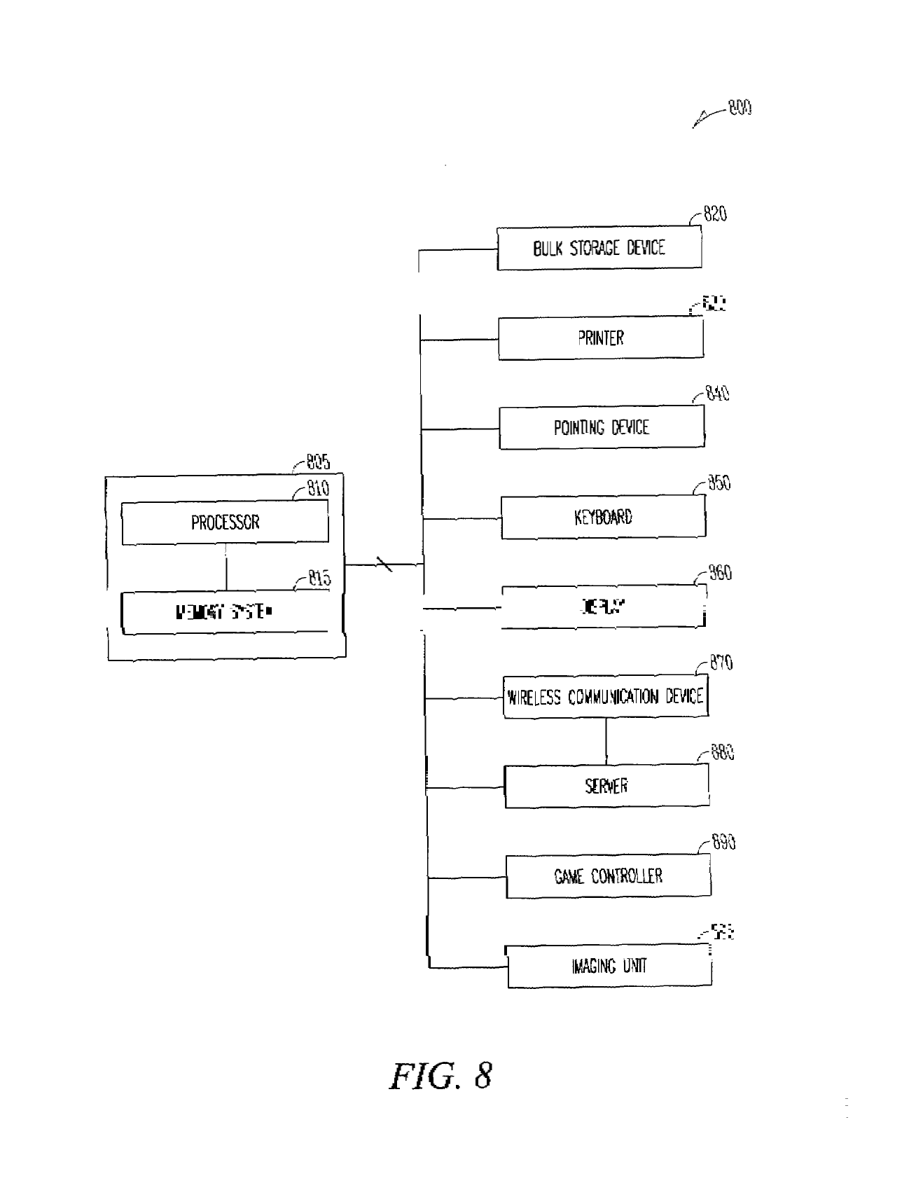

FIG. 8 illustrates a block diagram of an electronic system 800 according to various embodiment of the invention. An electronic system 800 may contain a processor 810, such as a microprocessor, microcontroller or digital signal processor, and a memory system 815 housed in a unit 805. The electronic system 800 optionally contains peripheral components, such as a keyboard 850, a pointing device 840, a monitor/display 860, a printer 830, a bulk storage device 820, a wireless communications device 870, a server 880, a game controller 890, and an imaging unit 895, such as an imager and a digital camera. Other components associated with the electronic system 800, such as modems, device driver cards, additional storage devices, etc. can also be included. The processor 810 and the memory system 815 of the electronic system 800 can be incorporated on a single integrated circuit. Such single package processing units may operate to reduce the communication time between the processor and the memory circuit. The processor 810 and the memory system 815 of the unit 805 may contain one or more floating gate devices 100, as shown in FIG. 1. Examples of a unit 805 include, a computer such as a personal computer, a network server such as a file server or an application server, video game device such as an XbOx™, a PlayStation™, a GameCube™ and a Game Boy™, a communications network such as wireless network and an optical network, analytical instrumentation, and medical diagnostics. In some embodiments, one or more of the printer 830, the bulk storage device 820, the network server 880, the wireless communications device 870, the monitor/display 860, the game controller 890, and the imaging unit 895 may contain an integrated circuit structure or element in accordance with embodiments of the invention, including one or more floating gate devices 100, as shown in FIG. 1.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims.

In the foregoing detailed description, various features are occasionally grouped together in a single embodiment for the purpose of streamlining the disclosure. This method of disclosure is not to be interpreted as reflecting an intention that the claimed embodiments of the subject matter require more features than are expressly recited in each claim. Rather, as the following claims reflect, invention may lie in less than all features of a single disclosed embodiment. Thus, the following claims are hereby incorporated into the detailed description, with each claim standing on its own as a separate preferred embodiment.

What is claimed is:

1. A nonvolatile memory comprising:
a first gate region adjoining a first insulator, the first insulator including a first dielectric constant;
a second insulator adjoining the first insulator and a third insulator, the second insulator including a second dielectric constant and the third insulator including a third dielectric constant, wherein the second dielectric constant is greater than at least one of the first dielectric constant and the third dielectric constant; and
a second gate region adjoining the third insulator, wherein the first gate region and the second gate region are electrically coupled across the first insulator, the second insulator and the third insulator.

2. The nonvolatile memory of claim 1, wherein the second insulator includes at least one of hafnium, aluminum, zirconium, scandium, lanthanum, titanium, tantalum, dysprosium, yttrium, and tungsten.

3. The nonvolatile memory of claim 1, wherein at least one of the first and the third insulator includes nitrogen.

4. The nonvolatile memory of claim 1, wherein at least one of the first insulator and the third insulator include a nitride.

5. The nonvolatile memory of claim 1, wherein the second insulator includes an oxide.

6. The nonvolatile memory of claim 1, wherein at least one of the first gate region and the second gate region includes a doped polysilicon material.

7. The nonvolatile memory of claim 1, wherein the first insulator and the third insulator are oxygen barrier layers.

8. The nonvolatile memory of claim 1, wherein the first insulator and the third insulator are configured to reduce an oxidation reaction.

9. The nonvolatile memory of claim 1, wherein the second insulator comprises a composite insulator.

10. The nonvolatile memory of claim 1, wherein the first insulator, the second insulator and the third insulator are configured to enhance a gate coupling ratio.

11. The nonvolatile memory of claim 1, wherein the first insulator, the second insulator and the third insulator are configured to reduce a gate leakage current.

12. A method comprising;
forming a first gate region;
forming a dielectric region adjoining the first gate region, wherein forming a dielectric region includes:
forming a first insulator adjoining the first gate region, the first insulator including a first dielectric constant;
forming a second insulator adjoining the first insulator, the second insulator including a second dielectric constant; and
forming a third insulator adjoining the second insulator, the third insulator including a third dielectric constant, wherein the second dielectric constant is greater than at least one of the first dielectric constant and the third dielectric constant; and
forming a second gate region adjoining the third insulator.

13. A method of claim 12, wherein at least one of forming a first gate region and forming a second region includes forming a region of doped polysilicon.

14. A method of claim 12, wherein forming a dielectric region includes forming to enhance a gate coupling ratio.

15. A method of claim 12, wherein forming a dielectric region includes forming to reduce a leakage current associated with the second gate region.

16. A method of claim 12, wherein forming a first insulator includes forming a first oxygen barrier and forming a third insulator includes forming a second oxygen barrier.

17. A method of claim 12, wherein at least one of forming a first insulator and forming a first third insulator includes forming a nitride.

18. A method of claim 12, wherein forming a dielectric region includes forming a second insulator comprising at least one of hafnium, aluminum, zirconium, scandium, lanthanum, titanium, tantalum, dysprosium, yttrium, and tungsten.

19. A method of claim 12, forming a second insulator includes forming a second insulator comprising at least one of oxygen and nitrogen.

20. A system comprising:
a processor including a floating gate region adjoining a dielectric region, the dielectric region comprising:
a first insulator having a first dielectric constant and contacting the floating gate region;
a second insulator having a second dielectric constant and contacting the first insulator and a third insulator, the third insulator having a third dielectric constant, wherein the second dielectric constant is greater than at least one of the first dielectric constant and the second dielectric constant; and
a control gate region contacting the third insulator, wherein the floating gate region is electrically coupled to the floating gate region across the dielectric region; and
a peripheral unit communicatively coupled to the processor.

21. The system of claim 20, wherein the peripheral unit includes a wireless communications device.

22. The system of claim 20, wherein the peripheral unit includes at least one of a memory unit, a display unit, a game controller, and a server.

23. The system of claim 20, wherein the processor includes at least one of a microprocessor, a digital signal processor and a microcontroller.

24. The system of claim 20, wherein the processor is adapted to form part of at least one of a video game device, a computer, and a communications network.

25. The system of claim 20, wherein the dielectric region is configured to at least one of enhance a gate coupling ratio and reduce a gate leakage current.

26. The system of claim 20, wherein the dielectric is configured to reduce oxidation of at least one of the floating gate region and the control gate region.

27. The system of claim 20, wherein at least one of the first insulator and the third insulator includes a nitride.

28. The system of claim 20, wherein the second insulator includes at least one of hafnium, aluminum, zirconium, scandium, lanthanum, titanium, tantalum, dysprosium, yttrium, and tungsten.

29. The system of claim 20, wherein at least one of the floating gate region and the control gate region includes a region of doped polysilicon.

30. The system of claim 20, wherein the second insulator includes at least one of a nitride, an oxide and an oxynitride.
